(19) United States
(12) Patent Application Publication
(10) Pub. No.: US 2024/0324344 A1
(43) Pub. Date: Sep. 26, 2024

(54) DISPLAY DEVICE AND METHOD OF MANUFACTURING THE SAME

(71) Applicant: Samsung Display Co., LTD., Yongin-si (KR)

(72) Inventor: HYUNEOK SHIN, Yongin-si (KR)

(21) Appl. No.: 18/505,851

(22) Filed: Nov. 9, 2023

(30) Foreign Application Priority Data
Mar. 21, 2023 (KR) 10-2023-0036302

(51) Int. Cl. H10K 59/131; H01L 23/00; H10K 59/12; H10K 59/90

(52) U.S. Cl. CPC H10K 59/131; H01L 24/05; H01L 24/29; H01L 24/32; H10K 59/1201; H10K 59/90; H01L 2224/05083; H01L 2224/05124; H01L 2224/05166; H01L 2224/05573; H01L 2224/05679; H01L 2224/0568; H01L 2224/05684; H01L 2924/0133

(57) ABSTRACT

A display device includes a substrate, a metal layer on the substrate and including titanium and aluminum, and an alloy layer on the metal layer and including molybdenum (Mo), tungsten (W), and niobium (Nb).

### CROSS-REFERENCE TO RELATED APPLICATION

The present application claims priority to and the benefit of Korean Patent Application No. 10-2023-0036302, filed on Mar. 21, 2023, in the Korean Intellectual Property Office, the entire content of which is hereby incorporated by reference.

### BACKGROUND

### 1. Field

Embodiments of the present disclosure relates to a display device. For example, embodiments of the present disclosure relate to a display device and a method of manufacturing the display device.

### 2. Description of the Related Art

Display devices are manufactured and utilized in various ways. The display device may provide visual information to a user by emitting light. To emit light, the display device may include one or more suitable light emitting elements. For example, the display device may include a liquid crystal display that emits light utilizing a liquid crystal layer (with, e.g., a backlight), an inorganic light emitting display that emits light utilizing an inorganic light emitting diode, an organic light emitting display that emits light utilizing an organic light emitting diode, and/or the like.

The light emitting diode may be to emit light based on a signal received from a driver. The driver may be disposed in a non-display area positioned around a display area where the light emitting diode is disposed. Lines, pads, etc., may be positioned in the non-display area in order to dispose the driver therein. An integrated circuit and a circuit film may be attached to the display device through the pad.

### SUMMARY

Aspects of one or more embodiments of the present disclosure relate to a display device with improved reliability.

Aspects of one or more embodiments of the present disclosure relate to a method for manufacturing the display device.

Additional aspects will be set forth in part in the description which follows and, in part, will be apparent from the description, or may be learned by practice of the presented embodiments of the disclosure.

A display device according to one or more embodiments of the present disclosure includes a substrate, a metal layer on the substrate and including titanium and aluminum, and an alloy layer on the metal layer and including molybdenum (Mo), tungsten (W), and niobium (Nb).

In one or more embodiments, the alloy layer may overlap the metal layer and contacts an upper surface of the metal layer.

In one or more embodiments, a content (e.g., amount) of niobium in the alloy layer may be about 5 at % to about 15 at % with respect to a total amount of elements in the alloy layer.

In one or more embodiments, a content (e.g., amount) of molybdenum in the alloy layer may be about 45 at % to about 55 at %, a content (e.g., amount) of tungsten in the alloy layer may be about 36 at % to about 44 at %, and a content (e.g., amount) of niobium in the alloy layer may be about 5 at % to about 15 at %, with respect to a total amount of elements in the alloy layer.

In one or more embodiments, the metal layer may include a first metal layer including titanium, a second metal layer on the first metal layer and including aluminum, and a third metal layer on the second metal layer and including titanium.

In one or more embodiments, the third metal layer may directly contact the alloy layer.

In one or more embodiments, a thickness of the alloy layer may be about 50 Å to about 100 Å.

In one or more embodiments, the metal layer may include a first metal layer including titanium and a second metal layer on the first metal layer and including aluminum.

In one or more embodiments, the second metal layer directly may contact the alloy layer.

In one or more embodiments, a thickness of the alloy layer may be about 250 Å to about 400 Å.

In one or more embodiments, the substrate may include a display area and a pad area adjacent to the display area, the metal layer may include a pad electrode in the pad area and a line in the display area, and the alloy layer may overlap an entirety of the metal layer (e.g., in a thickness direction of the display device or in a plan view of the display device).

In one or more embodiments, at least a portion of an upper surface of the alloy layer on the pad electrode may be exposed.

In one or more embodiments, the display device may further include an integrated circuit connected to the pad electrode and a conductive ball connecting the integrated circuit and the pad electrode.

In one or more embodiments, the conductive ball may penetrate the alloy layer and contacts the pad electrode.

A method of manufacturing a display device according to one or more embodiments of the present disclosure includes forming a metal layer including titanium and aluminum on a substrate and forming an alloy layer including molybdenum, tungsten, and niobium on the metal layer.

In one or more embodiments, a content (e.g., amount) of niobium may be about 5 at % to about 15 at % with respect to a total amount of elements in the alloy layer.

In one or more embodiments, a content (e.g., amount) of molybdenum in the alloy layer may be about 45 at % to about 55 at %, a content (e.g., amount) of tungsten in the alloy layer may be about 36 at % to about 44 at %, and a content (e.g., amount) of niobium in the alloy layer may be about 5 at % to about 15 at %, with respect to the total amount of elements in the alloy layer.

In one or more embodiments, the forming of the metal layer may include forming a first preliminary metal layer on the substrate, forming a second preliminary metal layer on the first preliminary metal layer, forming a third preliminary metal layer on the second preliminary metal layer, and concurrently (e.g., simultaneously) etching the first to third preliminary metal layers to form the metal layer, and the forming of the alloy layer may include forming a preliminary alloy layer on the third preliminary metal layer and etching the preliminary alloy layer to form the alloy layer.

In one or more embodiments, the method may further include disposing (e.g., applying) a conductive ball to penetrate the alloy layer and contact the metal layer.

In one or more embodiments, the forming of the metal layer may include forming a first preliminary metal layer on the substrate, forming a second preliminary metal layer on the first preliminary metal layer, and concurrently (e.g., simultaneously) etching the first and second preliminary metal layers to form the metal layer, and the forming of the alloy layer may include forming a preliminary alloy layer on the second preliminary metal layer and etching the preliminary alloy layer to form the alloy layer.

In the display device according to one or more embodiments of the present disclosure, an alloy layer including molybdenum, tungsten, and niobium may be on a metal layer including a line in a display area and a sub pad electrode in a pad area. Because the alloy layer with improved oxidation resistance entirely covers an upper surface of the metal layer, the alloy layer may prevent or substantially prevent the metal layer from being oxidized. Because oxidation of the metal layer is prevented or substantially prevented, contact resistance between a conductive ball and the metal layer may be reduced. In one or more embodiments, because the alloy layer has a relatively small thickness, high pressure may not be applied to a pad in order for the conductive ball to contact the metal layer. Thus, problems due to high pressure may be prevented or reduced.

In the manufacturing method of the display device according to one or more embodiments of the present disclosure, because the display device includes the alloy layer formed of molybdenum, tungsten, and niobium, the metal layer may be protected. Also, because an etching rate of a pixel electrode is low even after the alloy layer is formed, the plurality of pads exposed in a subsequent process may not be damaged or damage may be reduced.

It is to be understood that both the foregoing general description and the following detailed description are examples and are intended to provide further explanation of the present disclosure as claimed.

### BRIEF DESCRIPTION OF THE DRAWINGS

Illustrative, non-limiting embodiments will be more clearly understood from the following detailed description taken in conjunction with the accompanying drawings.

FIG. 1 is a perspective view illustrating a display device according to one or more embodiments of the present disclosure.

FIGS. 2 and 3 are each a plan view illustrating an enlarged area A of the display device of FIG. 1, according to embodiments of the present disclosure.

FIG. 4 is a cross-sectional view illustrating an integrated circuit disposed on pads in an area A of the display device of FIG. 1, according to one or more embodiments of the present disclosure.

FIG. 5 is cross-sectional view taken along line I-I′ of FIG. 1 and line II-II′ of FIG. 3, according to one or more embodiments of the present disclosure.

FIG. 6 is an enlarged cross-sectional view of area B of FIG. 5, according to one or more embodiments of the present disclosure.

FIG. 7 is a cross-sectional view of area B of FIG. 5, according to one or more embodiments of the present disclosure.

FIGS. 8 to 17 are cross-sectional views illustrating a manufacturing method of a display device according to one or more embodiments of the present disclosure.

FIGS. 18 and 19 are cross-sectional views illustrating a manufacturing method of a display device according to one or more embodiments of the present disclosure.

FIG. 20 is a graph showing a reflectance of the alloy layer over time.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

The illustrated embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

Unless otherwise noted, like reference numerals denote like elements throughout the attached drawings and the written description, and thus, duplicative descriptions thereof may not be provided. In the drawings, the relative sizes of elements, layers, and regions may be exaggerated for clarity.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Spatially relative terms, such as “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. The device may be otherwise oriented (e.g., rotated 90 degrees or at other orientations) and the spatially relative descriptors used herein should be interpreted accordingly.

It will be understood that when an element or layer is referred to as being “on,” or “connected to,” another element or layer, it can be directly on or connected to the other element or layer, or one or more intervening elements or layers may be present. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments only and is not intended to be limiting of the present disclosure. As used herein, the singular forms “a,” “an” and “the” are intended to include the plural forms as well, unless the context clearly indicates otherwise.

It will be further understood that the terms “comprises,” “comprising,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “and/or” includes any and all combinations of one or more of the associated listed items.

Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from a, b, and c,” “at least one from among a, b, and c,” “one from among a, b, and c”, “at least one of a to c” indicates only a, only b, only c, both a and b, both a and c, both b and c, all of a, b, and c, or variations thereof.

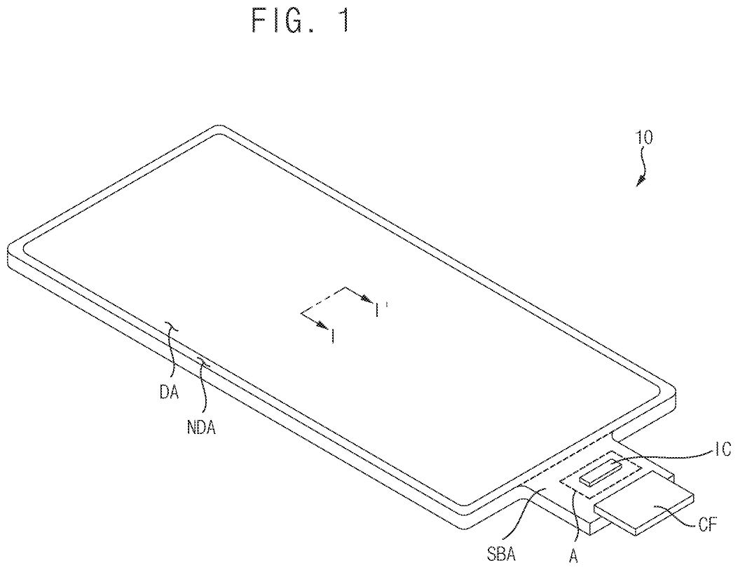

FIG. 1 is a perspective view illustrating a display device according to one or more embodiments of the present disclosure.

Referring to FIG. 1, a display device 10 may include a display area DA and a non-display area NDA. The display area DA may be defined as an area that emits light, and the non-display area NDA may be defined as an area where components for transmitting signals to the display area DA are disposed.

A plurality of pixels may be disposed in the display area DA. The plurality of pixels may be to emit light based on the signals transmitted from the non-display area NDA. The plurality of pixels may be generally disposed in the display area DA. Through this, an image may be displayed by emitting light in the display area DA (e.g., throughout the entirety of the display area DA).

A plurality of drivers may be disposed in the non-display area NDA. The plurality of drivers may generate and transmit the signals for driving the plurality of pixels, such as a gate signal, a light emitting signal, a data signal, a power supply voltage, and an initialization voltage.

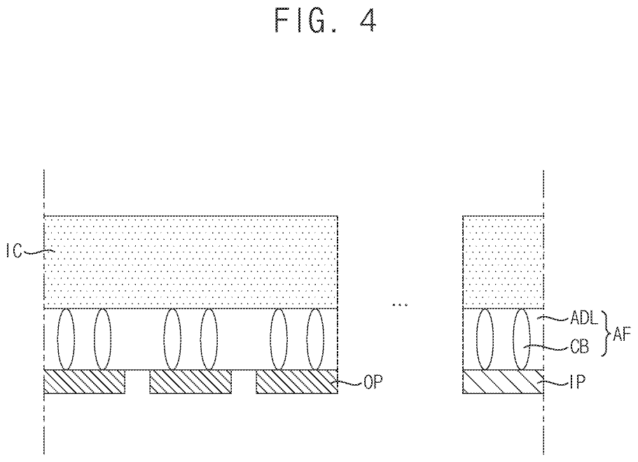

The non-display area NDA may include a pad area SBA. The pad area SBA may be adjacent to one side of the display area DA. In a completed product, the pad area SBA may be bent and positioned on a rear surface of the display device 10. For example, the pad area SBA may not be visually recognized (e.g., may not be seen) from a front surface of the display device 10 which is completed. An integrated circuit IC and a circuit film CF may be disposed in the pad area SBA. The integrated circuit IC and the circuit film CF may be connected to the pad area SBA by a conductive film (e.g., a conductive film AF of FIG. 4). The integrated circuit IC and the circuit film CF may generate and transmit signals transmitted to the plurality of pixels.

Although a chip on plastic (COP) method or a chip on glass (COG) method is illustrated as a method of disposing the integrated circuit IC in FIG. 1, the integrated circuit IC may (e.g., alternatively) be disposed in a chip on film (COF) method as well.

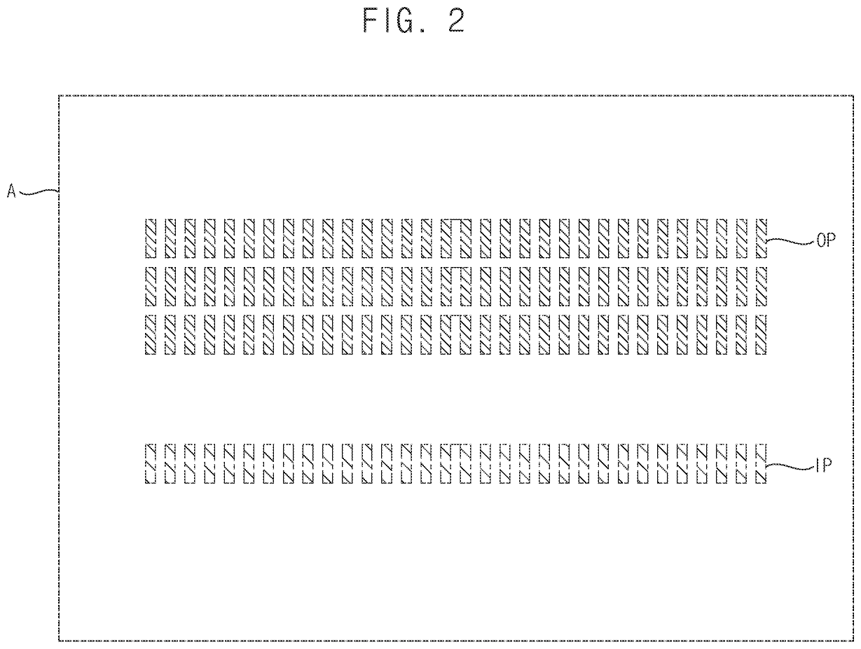

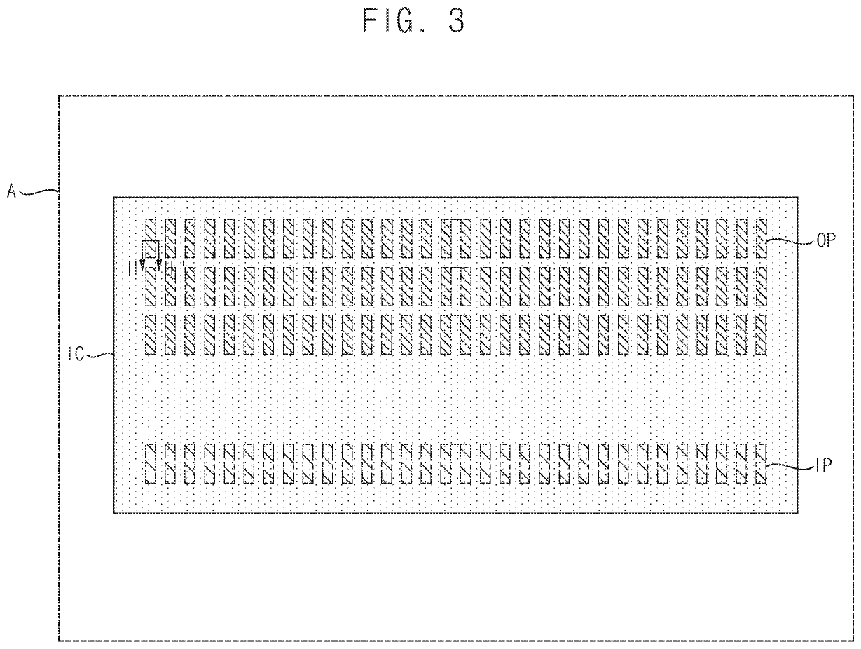

FIGS. 2 and 3 are plan views illustrating an enlarged area A of the display device of FIG. 1, according to one or more embodiments of the present disclosure.

Referring to FIGS. 1 and 2, a plurality of pads OP and IP may be disposed in the pad area SBA. The plurality of pads OP and IP may include output pads OP and input pads IP. The input pads IP may be spaced and/or apart from (e.g., separated from) each other in a line in one direction. The output pads OP may be spaced and/or apart from (e.g., separated from) each other in three lines in one direction. However, this is just an example, and the input pads IP may also be arranged in two or more lines, and the output pads IP may also be arranged in one line, two lines, three lines, or four or more lines.

Referring to FIG. 3 together, the integrated circuit IC may be disposed on the plurality of pads OP and IP. The integrated circuit IC may be connected to the plurality of pads OP and IP by the conductive film. The integrated circuit IC may output through the output pads OP an output signal generated based on an input signal transmitted through the input pads IP.

FIG. 4 is a cross-sectional view illustrating an integrated circuit disposed on pads disposed in an area A of the display device of FIG. 1, according to one or more embodiments of the present disclosure.

Referring to FIG. 4, the plurality of pads OP and IP may be electrically connected to the integrated circuit IC through a conductive film AF. For example, the conductive film AF may be an anisotropic conductive film. The conductive film AF may include an adhesive layer ADL and conductive balls CB. Because the adhesive layer ADL has insulating properties (e.g., is an insulator) and the conductive balls CB have conductivity (e.g., are conductors), the plurality of pads OP and IP may be electrically connected to the integrated circuit IC by the conductive balls CB. Accordingly, each of the conductive balls CB may directly contact at least one of the plurality of pads OP and/or IP and the integrated circuit IC.

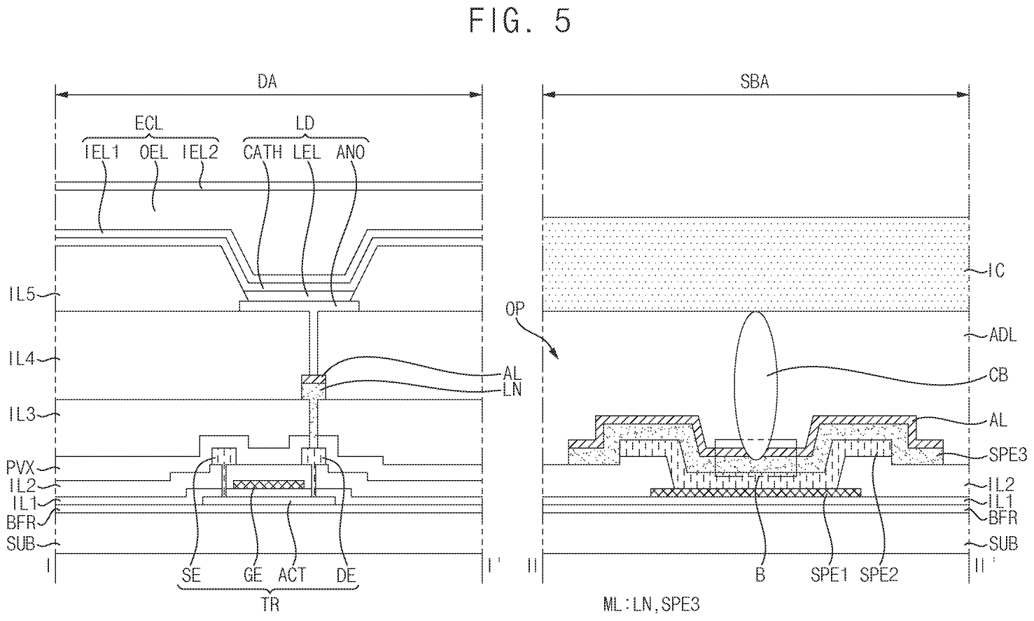

FIG. 5 is cross-sectional view taken along line I-I′ of FIG. 1 and line II-II′ of FIG. 3 according to one or more embodiments of the present disclosure.

Referring to FIGS. 1, 2, and 5, the display device 10 may include a substrate SUB, a first conductive layer, a second conductive layer, a metal layer ML, an alloy layer AL, a first insulating layer IL1, a second insulating layer IL2, a passivation layer PVX, a third insulating layer IL3, a fourth insulating layer IL4, a fifth insulating layer IL5, a light emitting diode LD, and an encapsulation layer ECL.

The substrate SUB may include the display area DA and the pad area SBA included in the non-display area NDA. The substrate SUB may include a flexible material or a rigid material. For example, the substrate SUB may include a polymer material such as polyimide, and in one or more embodiments, the substrate SUB may have a flexible property (e.g., may be flexible). In one or more embodiments, for example, the substrate SUB may include a material such as glass, and in such cases, the substrate SUB may have a rigid property (e.g., may be rigid).

A buffer layer BFR may be disposed on the substrate SUB. The buffer layer BFR may prevent or substantially prevent diffusion of metal atoms or impurities from the substrate SUB into the active layer ACT.

The active layer ACT may be disposed on the substrate SUB. The active layer ACT may be divided into a source region and a drain region doped with impurities and a channel region between the source region and the drain region.

The first insulating layer IL1 may be disposed on the buffer layer BFR. The first insulating layer IL1 may cover the active layer ACT and may be formed to have substantially the same thickness along a profile of the active layer ACT. However, the present disclosure is not limited thereto, and the first insulating layer IL1 may be disposed on the active layer ACT in a pattern form. For example, the first insulating layer IL1 may include an inorganic material.

The first conductive layer may be disposed on the first insulating layer IL1. The first conductive layer may include a gate electrode GE and a first sub pad electrode SPE1. The gate electrode GE may be disposed in the display area DA and may overlap the channel region of the active layer ACT. The first sub pad electrode SPE1 may be disposed in the pad area SBA.

The second insulating layer IL2 may be disposed on the first insulating layer IL1. In one or more embodiments, the second insulating layer IL2 may cover the gate electrode GE and may be disposed with substantially the same thickness along a profile of the gate electrode GE. In one or more embodiments, the second insulating layer IL2 may expose at least a portion of an upper surface of the first sub pad electrode SPE1.

The second conductive layer may be disposed on the second insulating layer IL2. The second conductive layer may include a source electrode SE, a drain electrode DE, and a second sub pad electrode SPE2. The source electrode SE and the drain electrode DE may be disposed in the display area DA. The source electrode SE may contact the source region of the active layer ACT through a first contact hole formed in the first and second insulating layers IL1 and IL2. The drain electrode DE may contact the drain region of the active layer ACT through a second contact hole formed in the first and second insulating layers IL1 and IL2. The second sub pad electrode SPE2 may be disposed in the pad area SBA. The second sub pad electrode SPE2 may overlap the first sub pad electrode SPE1 and may contact the first sub pad electrode SPE1.

The active layer ACT, the gate electrode GE, the source electrode SE, and the drain electrode DE may form a transistor TR.

The passivation layer PVX may be disposed on the second insulating layer IL2, for example, in the display area DA. In one or more embodiments, the passivation layer PVX may cover the source and drain electrodes SE and DE and may have substantially the same thickness along a profile of the source and drain electrodes SE and DE. However, the present disclosure is not limited thereto.

The third insulating layer IL3 may be disposed on the passivation layer PVX, for example, in the display area DA. The third insulating layer IL3 may have a substantially flat upper surface without generating a step around the passivation layer PVX. For example, the third insulating layer IL3 may include an organic material.

The metal layer ML may be disposed on the third insulating layer IL3. The metal layer ML may include a line LN and a third sub pad electrode SPE3. The line LN may be disposed in the display area DA. The line LN may be a line for transmitting a signal and may be a connection electrode for connecting conductive layers.

For example, the line LN may contact the source electrode SE or the drain electrode DE through a third contact hole formed in the third insulating layer IL3. The third sub pad electrode SPE3 may be disposed in the pad area SBA. The third sub pad electrode SPE3 may overlap the second sub pad electrode SPE2 and may contact the second sub pad electrode SPE2. Accordingly, the first to third sub pad electrodes SPE1, SPE2, and SPE3 may be electrically connected to each other.

The metal layer ML may include titanium (Ti) and aluminum (AI). The metal layer ML may have multiple layers.

The first to third sub pad electrodes SPE1, SPE2, and SPE3 may form one of the output pads OP or one of the input pads IP.

In one or more embodiments, the alloy layer AL may be entirely disposed on the metal layer ML. The alloy layer AL may entirely cover the metal layer ML and may overlap the metal layer ML. The alloy layer AL may contact an upper surface of the metal layer ML. Accordingly, the alloy layer AL may protect the upper surface of the metal layer ML. In one or more embodiments, at least a portion of an upper surface of the alloy layer AL disposed on the third sub pad electrode SPE3 may be exposed. Accordingly, the plurality of pads OP and IP may be connected to the integrated circuit IC through the conductive ball CB.

In one or more embodiments, the alloy layer AL may include molybdenum (Mo), tungsten (W), and niobium (Nb). The alloy layer AL may have a single layer.

The fourth insulating layer IL4 may be disposed on the third insulating layer IL3. In one or more embodiments, the fourth insulating layer IL4 may cover the line LN and the alloy layer AL, for example, in the display area DA, and have a substantially flat upper surface without generating a step around the line LN and the alloy layer AL. For example, the fourth insulating layer IL4 may include an organic material.

The pixel electrode ANO may be disposed on the fourth insulating layer IL4, for example, in the display area DA. The pixel electrode ANO may have a reflection or light transmission properties. For example, the pixel electrode ANO may include metal.

The pixel electrode ANO may contact the connection electrode (e.g., the line LN with the alloy layer AL) through a fourth contact hole formed in the fourth insulating layer IL4. Through this, the pixel electrode ANO may be connected to the transistor TR.

The fifth insulating layer IL5 may be disposed on the fourth insulating layer IL4, and an opening exposing an upper surface of the pixel electrode ANO may be defined in the fifth insulating layer IL5. For example, the fifth insulating layer IL5 may include an organic material or an inorganic material.

The light emitting layer LEL may be disposed on the pixel electrode ANO. The light emitting layer LEL may be disposed in the opening formed in the fifth insulating layer IL5. In one or more embodiments, the light emitting layer LEL may have a multilayer structure including a hole injection layer, a hole transport layer, an organic light emitting layer, an electron transport layer, and/or an electron injection layer. The organic light emitting layer may include a light emitting material.

The common electrode CATH may cover the light emitting layer LEL and may be disposed on the fifth insulating layer IL5. In one or more embodiments, the common electrode CATH may have a plate shape. Also, the common electrode CATH may have light transmission or reflection properties. For example, the common electrode CATH may include metal.

The pixel electrode ANO, the light emitting layer LEL, and the common electrode CATH may form the light emitting diode LD.

The encapsulation layer ECL may prevent or reduce penetration of moisture and oxygen into the light emitting diode LD from the outside. For example, the encapsulation layer ECL may include a first inorganic encapsulation layer IEL1, an organic encapsulation layer OEL, and a second inorganic encapsulation layer IEL2.

The first inorganic encapsulation layer IEL1 may be disposed on the common electrode CATH and have substantially the same thickness along a profile of the common electrode CATH. The organic encapsulation layer OEL may be disposed on the first inorganic encapsulation layer IEL1 and may have a substantially flat upper surface without generating a step around the first inorganic encapsulation layer IEL1. The second inorganic encapsulation layer IEL2 may be disposed on the organic encapsulation layer OEL.

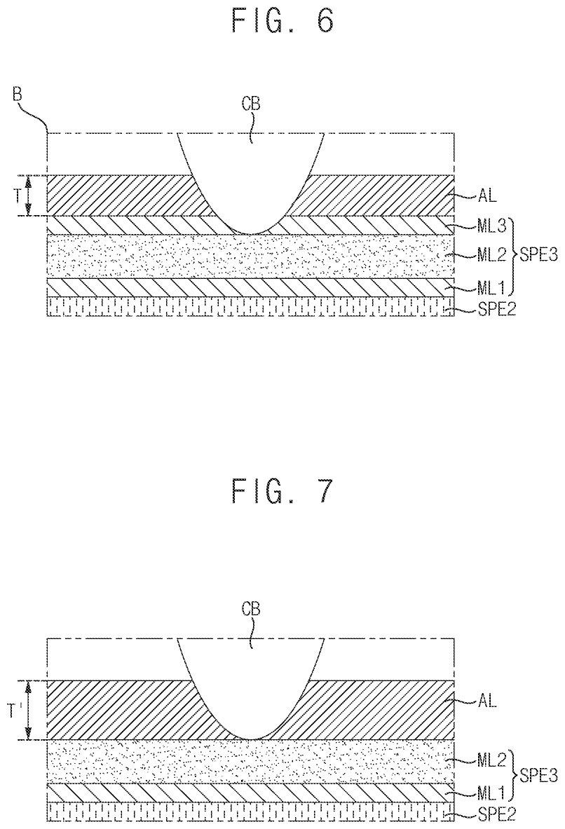

FIG. 6 is an enlarged cross-sectional view of area B of FIG. 5, according to one or more embodiments of the present disclosure.

Referring to FIG. 6, the metal layer ML may include a first metal layer ML1, a second metal layer ML2, and a third metal layer ML3. The second metal layer ML2 may be disposed on the first metal layer ML1, and the third metal layer ML3 may be disposed on the second metal layer ML2. The third metal layer ML3 may directly contact the alloy layer AL.

The first metal layer ML1 may include titanium, the second metal layer ML2 may include aluminum, and the third metal layer ML3 may include titanium. However, the present disclosure is not limited thereto.

In one or more embodiments, the alloy layer AL may include molybdenum, tungsten, and niobium. When a total amount of elements included in the alloy layer AL is 100 at %, a content (e.g., amount) of niobium may be about 5 at % to about 15 at %. For example, a total amount of molybdenum and tungsten included in the alloy layer AL may be about 85 at % to about 95 at %.

For example, a content (e.g., amount) of molybdenum included in the alloy layer AL may be about 45 at % to about 55 at %. A content (e.g., amount) of tungsten included in the alloy layer AL may be about 36 at % to about 44 at %. A content (e.g., amount) of niobium included in the alloy layer AL may be about 5 at % to about 15 at %. However, the present disclosure is not limited thereto.

Also, a thickness T of the alloy layer AL may be about 50 Å to about 100 Å. If (e.g., when) the thickness T of the alloy layer AL is smaller than about 50 Å, it may be difficult to control a material forming the alloy layer AL when forming the alloy layer AL. In one or more embodiments, if (e.g., when) the thickness T of the alloy layer AL is greater than about 100 Å, by-products may be excessively generated during etching of the alloy layer AL. The by-product may affect a process of etching the metal layer ML after etching the alloy layer AL. Accordingly, as the thickness T of the alloy layer AL increases, an amount of the by-product generated increases, and thus, an effect on a process of forming the metal layer ML may increase.

In one or more embodiments, the conductive ball CB may contact the metal layer ML. The conductive ball CB may penetrate the alloy layer AL and contact the third sub pad electrode SPE3 included in the metal layer ML. In more detail, the conductive ball CB may penetrate up to the third metal layer ML3 and may contact the second metal layer ML2. Through this, the conductive ball CB may connect the integrated circuit IC and at least one of the plurality of pads OP and/or IP.

In one or more embodiments, in the display device 10, the alloy layer AL including molybdenum, tungsten, and niobium may be disposed on the metal layer ML including the line LN in the display area DA and the sub pad electrode SPE3 in the pad area SBA. Because the alloy layer AL with improved oxidation resistance entirely covers the upper surface of the metal layer ML, the alloy layer AL may prevent or substantially prevent the metal layer ML from being oxidized. Because oxidation of the metal layer ML is prevented or reduced, contact resistance between the conductive ball CB and the metal layer ML may be reduced. In one or more embodiments, because the alloy layer AL has a relatively small thickness, high pressure may not be applied to the plurality of pads OP and IP in order for the conductive ball CB to contact the metal layer ML. Thus, problems due to high pressure may be prevented or reduced.

FIG. 7 is a cross-sectional view illustrating another example of FIG. 6, according to one or more embodiments of the present disclosure.

Referring to FIG. 7, the metal layer ML may include a first metal layer ML1 and a second metal layer ML2. The second metal layer ML2 may be disposed on the first metal layer ML1. The second metal layer ML2 may directly contact the alloy layer AL.

The first metal layer ML1 may include titanium, and the second metal layer ML2 may include aluminum. However, the present disclosure is not limited thereto.

In one or more embodiments, the alloy layer AL may include molybdenum, tungsten, and niobium. When a total amount of elements included in the alloy layer AL is 100 at % (e.g., with respect to the total amount of elements in the alloy layer AL), a content (e.g., amount) of niobium may be about 5 at % to about 15 at %. For example, a content (e.g., amount) of molybdenum included in the alloy layer AL may be about 45 at % to about 55 at %. A content (e.g., amount) of tungsten included in the alloy layer AL may be about 36 at % to about 44 at %, with respect to the total amount of elements in the alloy layer AL. However, the present disclosure is not limited thereto.

Also, a thickness T′ of the alloy layer AL may be about 250 Å to about 400 Å. If (e.g., when) the thickness T′ of the alloy layer AL is smaller than about 250 Å, durability of the metal layer ML and the alloy layer AL in the pad area SBA may deteriorate. In one or more embodiments, if (e.g., when) the thickness T′ of the alloy layer AL is greater than about 400 Å, by-products may be excessively generated during etching of the alloy layer AL. The by-product may affect a process of etching the metal layer ML after etching the alloy layer AL. Accordingly, as the thickness T′ of the alloy layer AL increases, an amount of the by-product generated increases, and thus, an effect on a process of forming the metal layer ML may increase.

In one or more embodiments, the conductive ball CB may contact the metal layer ML. The conductive ball CB may penetrate the alloy layer AL and contact the third sub pad electrode SPE3 included in the metal layer ML. For example, the conductive ball CB may penetrate the alloy layer AL and may contact the second metal layer ML2. Through this, the conductive ball CB may connect the integrated circuit IC and at least one of the plurality of pads OP and/or IP.

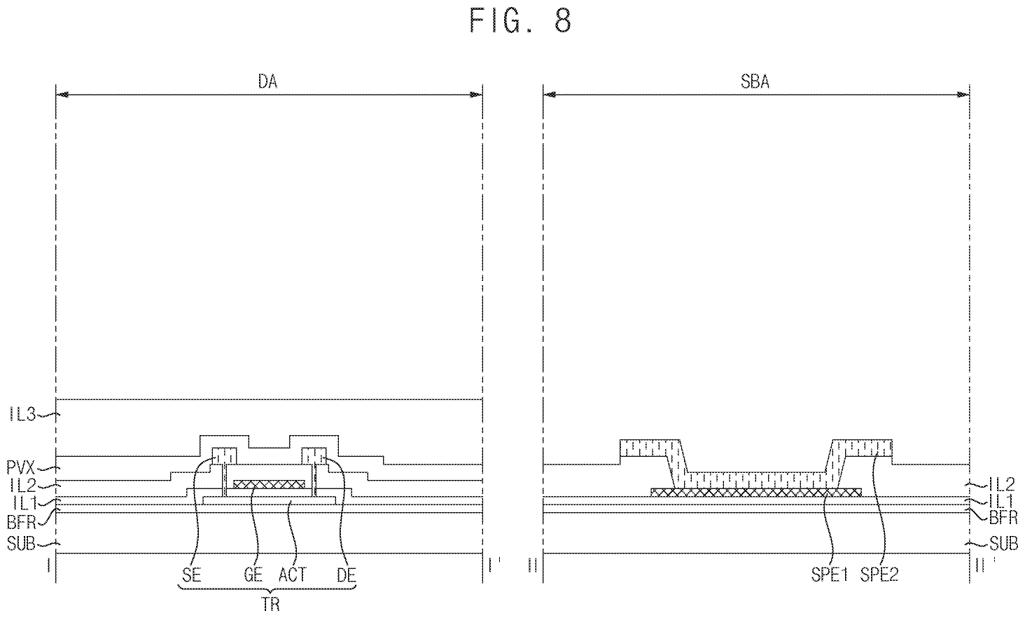

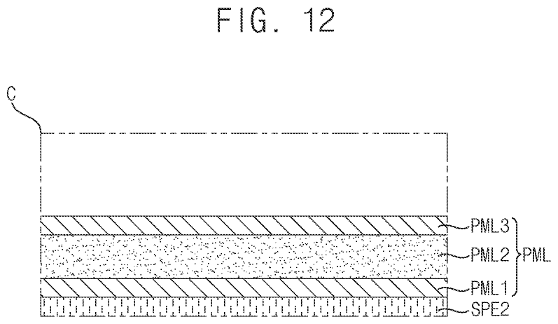

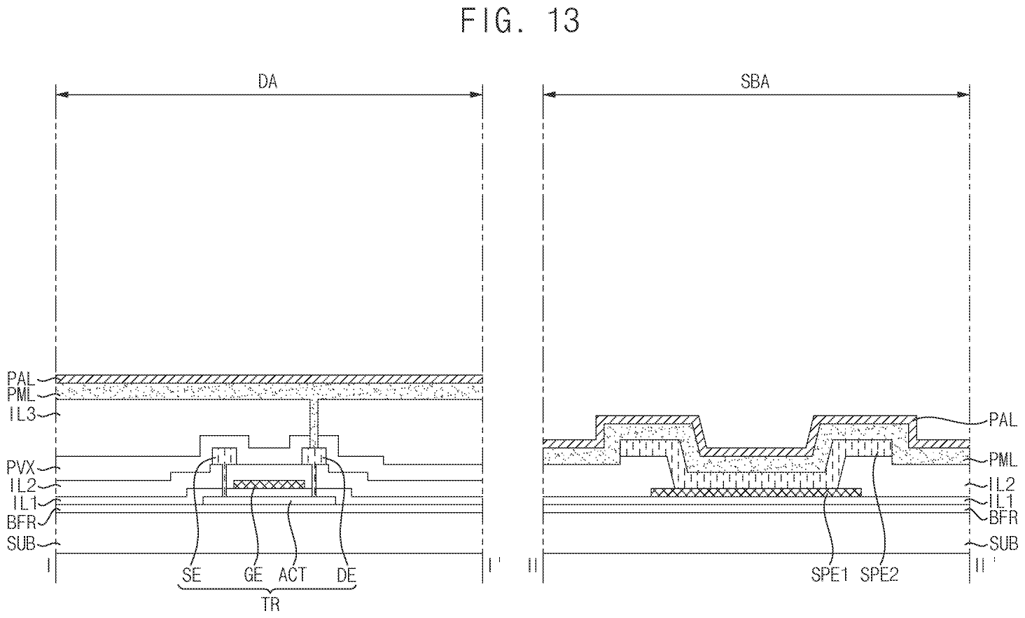

FIGS. 8 to 17 are cross-sectional views illustrating a manufacturing method of a display device according to one or more embodiments of the present disclosure.

For example, a manufacturing method of the display device described with reference to FIGS. 8 to 17 may be a method of manufacturing the display device according to one or more embodiments of FIGS. 5 and 6.

Referring to FIG. 8, the buffer layer BFR may be formed on the substrate SUB. The active layer ACT may be formed on the buffer layer BFR. The first insulating layer IL1 may be formed on the buffer layer BFR to cover the active layer ACT. The first conductive layer may be formed on the first insulating layer IL1. The first conductive layer may include the gate electrode GE and the first sub pad electrode SPE1. The gate electrode GE may be formed in the display area DA, and the first sub pad electrode SPE1 may be formed in the pad area SBA. The second insulating layer IL2 may be formed on the first insulating layer IL1 to cover the first conductive layer. The second conductive layer may be formed on the second insulating layer IL2. The second conductive layer may include the source electrode SE, the drain electrode DE, and the second sub pad electrode SPE2. The source electrode SE and the drain electrode DE may be formed in the display area DA, and the second sub pad electrode SPE2 may be formed in the pad area SBA. The passivation layer PVX may be formed on the second insulating layer IL2 to cover the second conductive layer, for example, in the display area DA. The third insulating layer IL3 may be formed on the passivation layer PVX, for example, in the display area DA.

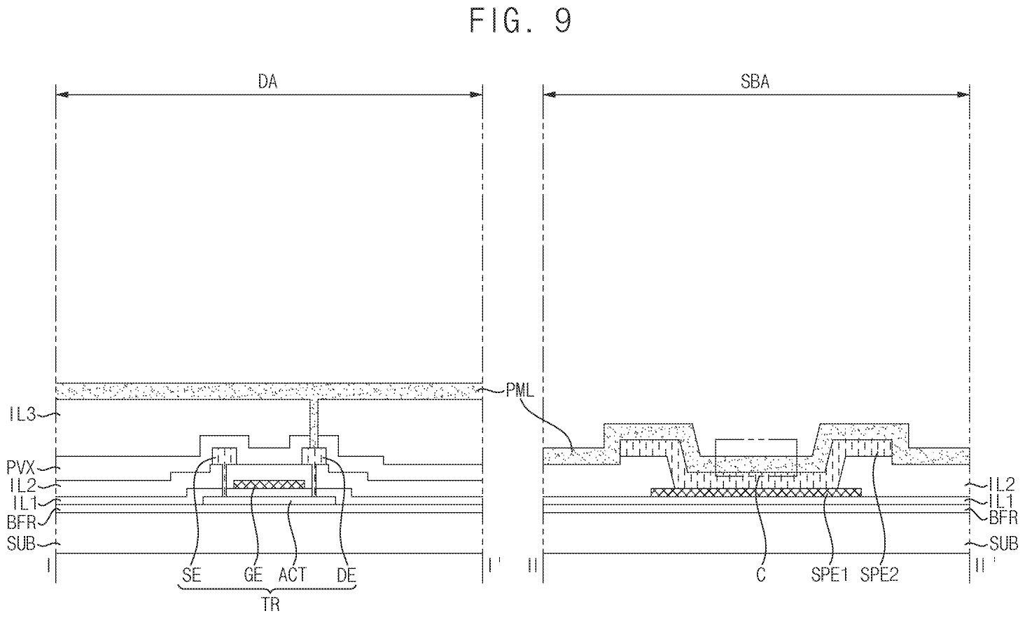

Referring to FIG. 9, a preliminary metal layer PML may be formed on the third insulating layer IL3 and/or the second insulating layer IL2 in the non-display area NDA. The preliminary metal layer PML may include titanium and aluminum. The preliminary metal layer PML may be connected to the source electrode SE or the drain electrode DE in the display area DA. Also, the preliminary metal layer PML may cover the second sub pad electrode SPE2 in the pad area SBA. For example, the preliminary metal layer PML may contact an upper surface of the second sub pad electrode SPE2 and be connected to the second sub pad electrode SPE2.

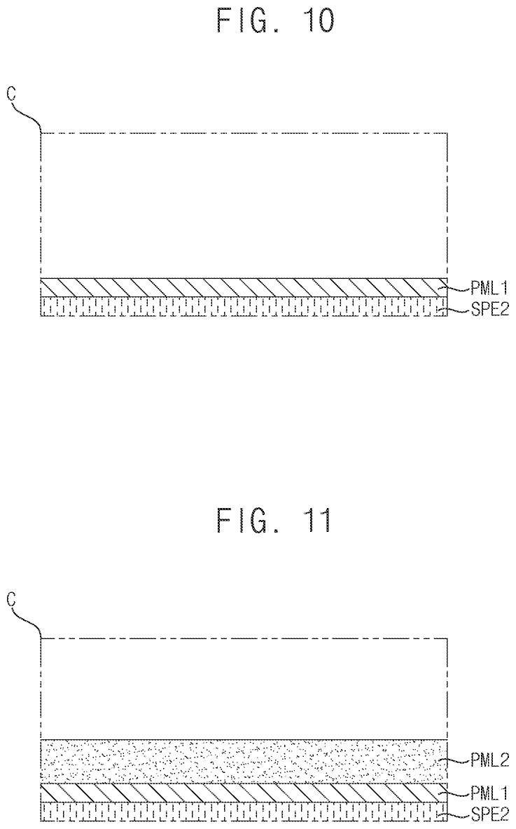

FIGS. 10 to 12 are views illustrating manufacturing steps (e.g., tasks or acts) of the preliminary metal layer, according to one or more embodiments of the present disclosure. For example, FIGS. 10 to 12 are enlarged cross-sectional views of area C of FIG. 9.

Referring to FIGS. 10 to 12, the preliminary metal layer PML may be formed in multiple layers. A first preliminary metal layer PML1 may be formed on the second sub pad electrode SPE2 to cover the second sub pad electrode SPE2. The first preliminary metal layer PML1 may include titanium. A second preliminary metal layer PML2 may be formed on the first preliminary metal layer PML1. The second preliminary metal layer PML2 may include aluminum. A third preliminary metal layer PML3 may be formed on the second preliminary metal layer PML2. The third preliminary metal layer PML3 may include titanium. Accordingly, the preliminary metal layer PML including the first to third preliminary metal layers PML1, PML2, and PML3 may be formed.

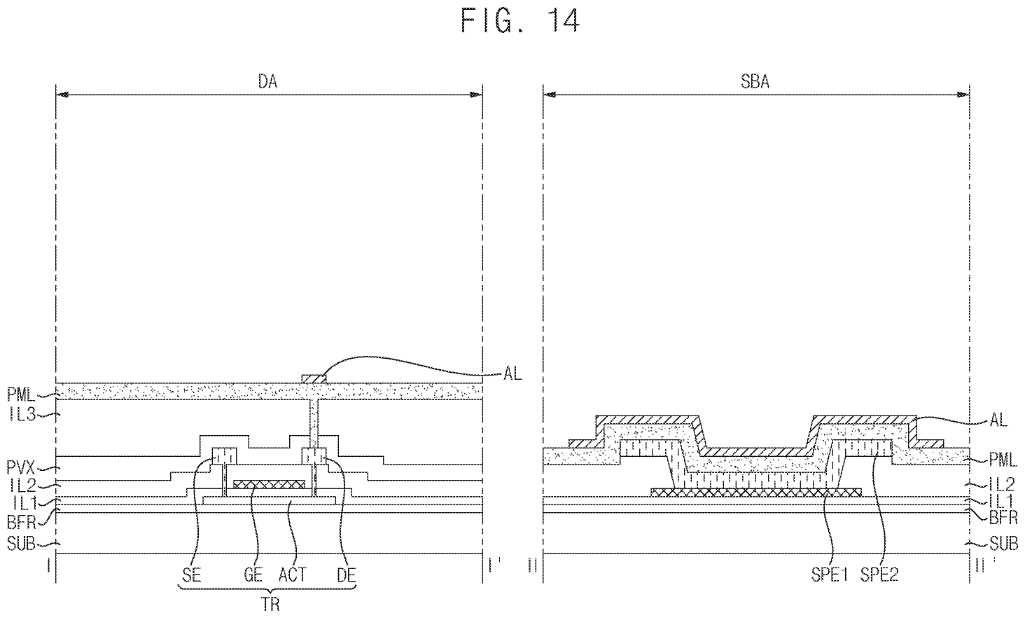

Further, referring to FIG. 13, a preliminary alloy layer PAL may be formed on the preliminary metal layer PML. For example, the preliminary alloy layer PAL may be formed on the third preliminary metal layer PML3. The preliminary alloy layer PAL may be formed of molybdenum, tungsten, and niobium.

In one or more embodiments, when a total amount of elements forming the preliminary alloy layer PAL is 100 at % (e.g., with respect to the total amount of elements in the preliminary alloy layer PAL), a content (e.g., amount) of niobium may be about 5 at % to about 15 at %. For example, a content (e.g., amount) of molybdenum forming the preliminary alloy layer PAL may be about 45 at % to about 55 at %. A content (e.g., amount) of tungsten forming the preliminary alloy layer PAL may be about 36 at % to about 44 at % with respect to the total amount of elements in the preliminary alloy layer PAL). However, the present disclosure is not limited thereto.

Referring to FIG. 14, the alloy layer AL may be formed by etching the preliminary alloy layer PAL. The alloy layer AL may be etched through a dry etching process. In the dry etching process for forming the alloy layer AL, the preliminary alloy layer PAL may be etched utilizing a gas containing fluorine (F). However, the present disclosure is not limited thereto.

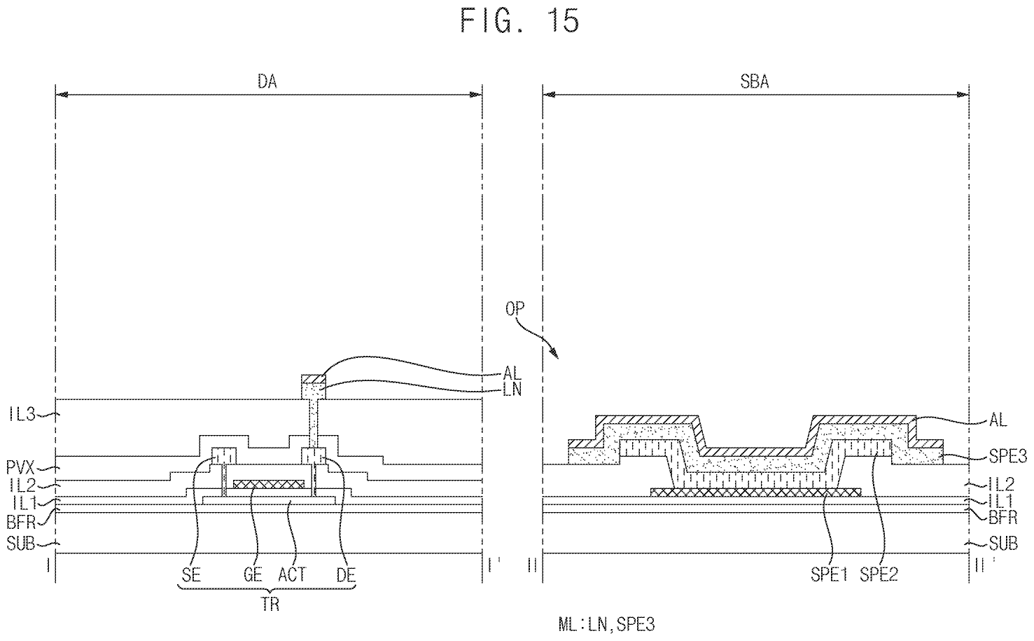

Referring to FIG. 15, the metal layer ML may be formed by etching the preliminary metal layer PML. The metal layer ML may be formed by concurrently (e.g., simultaneously) etching the first to third preliminary metal layers PML1, PML2, and PML3.

The metal layer ML may be etched through a dry etching process. In the dry etching process for forming the metal layer ML, the preliminary metal layer PML may be etched utilizing a gas containing chlorine (CI). However, the present disclosure is not limited thereto.

The preliminary metal layer PML may be formed in substantially the same shape as the preliminary alloy layer PAL. Accordingly, the alloy layer AL may entirely overlap the metal layer ML (e.g., may entirely overlap the metal layer in a thickness direction of the display device 10 or in a plan view of the display device 10).

The metal layer ML may include the line LN disposed in the display area DA and the third sub pad electrode SPE3 disposed in the pad area SBA. The first to third sub pad electrodes SPE3 may form one of the plurality of pads OP and/or IP.

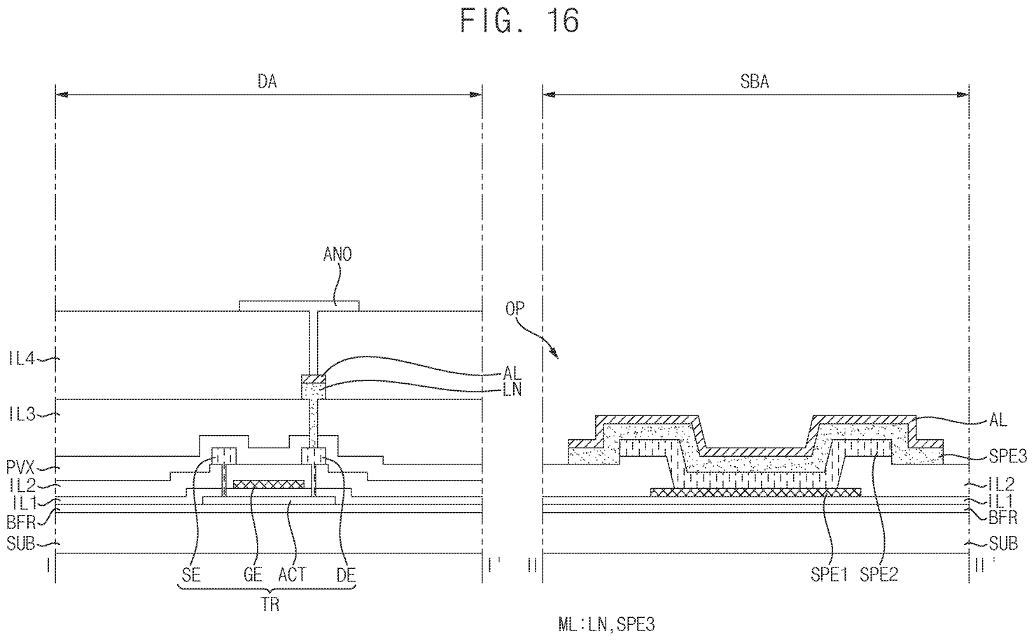

Referring further to FIG. 16, the fourth insulating layer IL4 may be formed on the third insulating layer IL3 to cover the metal layer ML and the alloy layer AL, for example, in the display area DA. The pixel electrode ANO may be formed on the fourth insulating layer IL4. The pixel electrode ANO may be connected to the alloy layer AL.

In the process of forming the pixel electrode ANO, the pixel electrode ANO may be formed through a wet etching process. At this time, an etching rate of the alloy layer AL with respect to an etchant utilized to form the pixel electrode ANO may converge to zero. The etchant may include phosphoric acid, nitric acid, acetic acid, and/or the like. Accordingly, the alloy layer AL and the pads OP and IP may not be damaged even in the etchant and may maintain their original shapes.

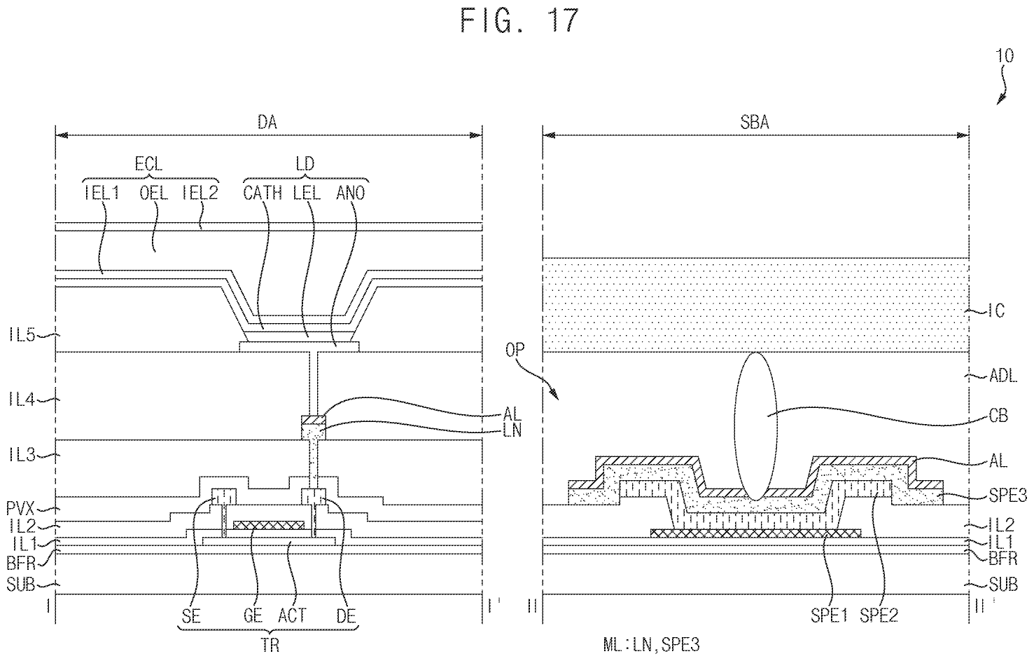

Referring to FIG. 17, the fifth insulating layer IL5 may be formed on the fourth insulating layer IL4. The light emitting layer LEL may be formed on the pixel electrode ANO. The common electrode CATH may be disposed on the fifth insulating layer IL5 and the light emitting layer LEL. The first inorganic encapsulation layer IEL1 may be formed on the common electrode CATH. The organic encapsulation layer OEL may be formed on the first inorganic encapsulation layer IEL1. The second inorganic encapsulation layer IEL2 may be formed on the organic encapsulation layer OEL.

The conductive film AF may be formed on the alloy layer AL in the pad area SBA. The conductive film AF may include the adhesive layer ADL and the conductive balls CB. For example, the conductive balls CB may penetrate the alloy layer AL and contact the metal layer ML. Also, the adhesive layer ADL may fix the integrated circuit IC to the pads OP and IP.

In one or more embodiments, because the display device 10 includes the alloy layer AL formed of molybdenum, tungsten, and niobium, the metal layer ML may be protected. Also, because the etching rate of the pixel electrode ANO is low even after the alloy layer AL is formed, the plurality of pads OP and IP exposed in a subsequent process may not be damaged.

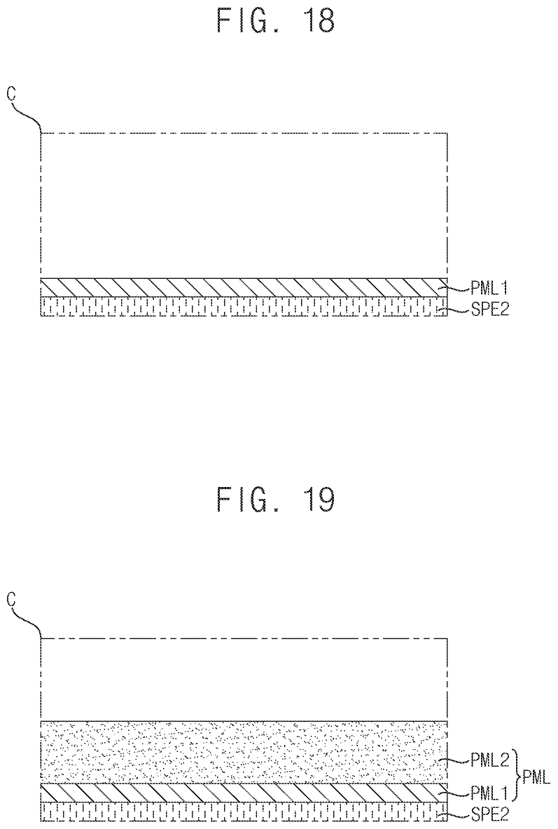

FIGS. 18 and 19 are views illustrating a manufacturing method of a display device according to one or more embodiments of the present disclosure.

For example, a manufacturing method of the display device described with reference to FIGS. 18 and 19 may be a method of manufacturing the display device according to one or more embodiments of FIGS. 5 and 7. In one or more embodiments, the manufacturing method of the display device described with reference to FIGS. 18 and 19 may be same as the manufacturing method of the display device described with reference to FIGS. 8 to 17 except for a step of forming the metal layer. Therefore, redundant descriptions may not be provided or may be simplified.

FIGS. 18 and 19 may illustrate another example of FIGS. 10 to 12. FIGS. 18 and 19 are views illustrating manufacturing steps of forming the preliminary metal layer.

Referring to FIGS. 18 and 19, a preliminary metal layer PML may be formed in multiple layers. A first preliminary metal layer PML1 may be formed on the second sub pad electrode to cover the second sub pad electrode. The first preliminary metal layer PML1 may include titanium. A second preliminary metal layer PML2 may be formed on the first preliminary metal layer PML1. The second preliminary metal layer PML2 may include aluminum. Accordingly, the preliminary metal layer PML including the first and second preliminary metal layers PML2 may be formed.

The preliminary alloy layer PAL may be formed on the preliminary metal layer PML. For example, the preliminary alloy layer PAL may be formed on the second preliminary metal layer PML2. The preliminary alloy layer PAL may be formed of molybdenum, tungsten, and niobium.

In one or more embodiments, the alloy layer AL may be formed by etching the preliminary alloy layer PAL, and the metal layer ML may be formed by etching the preliminary metal layer PML. The first and second preliminary metal layers PML1 and PML2 may be concurrently (e.g., simultaneously) etched to form the metal layer ML.

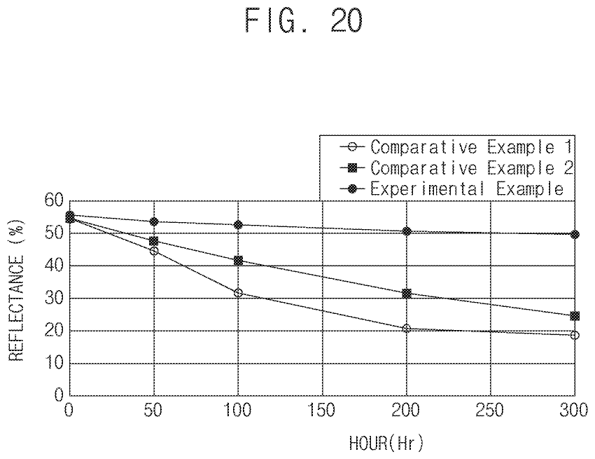

FIG. 20 is a graph showing a reflectance of the alloy layer over time.

Referring to FIG. 20, alloy layers according to Comparative Example 1, Comparative Example 2, and an Experimental Example were prepared, respectively.

TABLE 1

| | Comparative | Comparative | Experimental |
|---|---|---|---|
| | Example 1 | Example 2 | Example |
| A content (e.g., | 100 | 90 | 50 |
| amount) of | | | |
| molybdenum (at %) | | | |
| A content (e.g., | — | — | 40 |
| amount) of | | | |
| tungsten (at %) | | | |
| A content (e.g., | — | 10 | 10 |
| amount) of | | | |
| niobium (at %) | | | |

In the Experimental Example and Comparative Examples under conditions of 85° C. and 85% humidity, change in reflectance over time was measured. Through this, it can be confirmed that the change in reflectance of the alloy layer according to the Experimental Example is smaller than that of the alloy layers according to the Comparative Examples. Therefore, it can be confirmed that reliability of the alloy layer according to the Experimental Example is superior to reliability of the alloy layers as compared to that of (or according to) the Comparative Examples. Accordingly, reliability of the display device including the alloy layer according to embodiments of the present disclosure may be improved.

The present disclosure should not be construed as being limited to the embodiments set forth herein. Rather, these embodiments are provided so that this disclosure will be thorough and complete and to fully convey the concept of the present disclosure to those skilled in the art.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within +30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Further, the use of “may” when describing embodiments of the present disclosure refers to “one or more embodiments of the present disclosure.”

The light emitting device, electronic apparatus or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although embodiments of the present disclosure have been described, it is understood that the present disclosure should not be limited to these embodiments, but one or more suitable changes and modifications can be made by one ordinary skilled in the art within the spirit and scope of the present disclosure as defined by the following claims and equivalents thereof.

What is claimed is:

1. A display device comprising:
a substrate;
a metal layer on the substrate and comprising titanium (Ti) and aluminum (Al); and
an alloy layer on the metal layer and comprising molybdenum (Mo), tungsten (W), and niobium (Nb).

2. The display device of claim 1, wherein the alloy layer overlaps the metal layer and contacts an upper surface of the metal layer.

3. The display device of claim 1, wherein an amount of niobium in the alloy layer is about 5 at % to about 15 at % with respect to a total amount of elements in the alloy layer.

4. The display device of claim 3, wherein an amount of molybdenum in the alloy layer is about 45 at % to about 55 at %, an amount of tungsten in the alloy layer is about 36 at % to about 44 at %, and an amount of niobium in the alloy layer is about 5 at % to about 15 at %, with respect to the total amount of elements in the alloy layer.

5. The display device of claim 1, wherein the metal layer comprises:
a first metal layer comprising titanium;
a second metal layer on the first metal layer and comprising aluminum; and
a third metal layer on the second metal layer and comprising titanium.

6. The display device of claim 5, wherein the third metal layer directly contacts the alloy layer.

7. The display device of claim 5, wherein a thickness of the alloy layer is about 50 Å to about 100 Å.

8. The display device of claim 1, wherein the metal layer comprises:
a first metal layer comprising titanium; and
a second metal layer on the first metal layer and comprising aluminum.

9. The display device of claim 8, wherein the second metal layer directly contacts the alloy layer.

10. The display device of claim 8, wherein a thickness of the alloy layer is about 250 Å to about 400 Å.

11. The display device of claim 1, wherein the substrate comprises a display area and a pad area adjacent to the display area,
the metal layer comprises a pad electrode in the pad area and a line in the display area, and
the alloy layer overlaps an entirety of the metal layer in a plan view of the display device.

12. The display device of claim 11, wherein at least a portion of an upper surface of the alloy layer on the pad electrode is exposed.

13. The display device of claim 11, further comprising:
an integrated circuit connected to the pad electrode; and
a conductive ball connecting the integrated circuit and the pad electrode.

14. The display device of claim 13, wherein the conductive ball penetrates the alloy layer and contacts the pad electrode.

15. A method of manufacturing a display device, the method comprising:
forming a metal layer comprising titanium (Ti) and aluminum (Al) on a substrate; and
forming an alloy layer comprising molybdenum (Mo), tungsten (W), and niobium (Nb) on the metal layer.

16. The method of claim 15, wherein an amount of niobium is about 5 at % to about 15 at % with respect to a total amount of elements in the alloy layer.

17. The method of claim 15, wherein an amount of molybdenum in the alloy layer is about 45 at % to about 55 at %, an amount of tungsten in the alloy layer is about 36 at % to about 44 at %, and an amount of niobium in the alloy layer is about 5 at % to about 15 at %, with respect to the total amount of elements in the alloy layer.

18. The method of claim 16, wherein
the forming of the metal layer comprises:
forming a first preliminary metal layer on the substrate;
forming a second preliminary metal layer on the first preliminary metal layer;
forming a third preliminary metal layer on the second preliminary metal layer; and
concurrently etching the first to third preliminary metal layers to form the metal layer, and
the forming of the alloy layer comprises:
forming a preliminary alloy layer on the third preliminary metal layer; and
etching the preliminary alloy layer to form the alloy layer.

19. The method of claim 18, further comprising:
applying a conductive ball to penetrate the alloy layer and contact the metal layer.

20. The method of claim 16, wherein
the forming of the metal layer comprises:
forming a first preliminary metal layer on the substrate;
forming a second preliminary metal layer on the first preliminary metal layer; and
concurrently etching the first and second preliminary metal layers to form the metal layer, and
the forming of the alloy layer comprises:
forming a preliminary alloy layer on the second preliminary metal layer; and
etching the preliminary alloy layer to form the alloy layer.
